(19) United States
(12) Patent Application Publication
(10) Pub. No.: US 2020/0203234 A1
(43) Pub. Date: Jun. 25, 2020

(54) METHOD OF FORMING HIGH ASPECT RATIO FEATURES IN SEMICONDUCTOR SUBSTRATE

(71) Applicant: XIA TAI XIN SEMICONDUCTOR (QING DAO) LTD., Qingdao (CN)

(72) Inventor: DONG-HOON KANG, Singapore (SG)

(21) Appl. No.: 16/692,700

(22) Filed: Nov. 22, 2019

Related U.S. Application Data
(60) Provisional application No. 62/779,473, filed on Dec. 14, 2018.

(51) Int. Cl. H01L 21/66; H01L 27/108

(52) U.S. Cl. CPC H01L 22/26; H01L 27/1087

(57) ABSTRACT

The present disclosure provides a method of forming high aspect ratio (HAR) features in a semiconductor substrate. The substrate is placed in a processing chamber of an etching apparatus. A first nitride layer of the substrate is etched towards a first oxide layer of the substrate for a predetermined duration. The first oxide layer of the substrate is etched towards a second nitride layer of the substrate while monitoring a parameter in the processing chamber by an end point detector of the etching apparatus. A control unit of the etching apparatus determines whether the parameter in the processing chamber detected by the end point detector exceeds a predetermined value. If the parameter detected by the end point detector exceeds the predetermined value, an etching end point is marked for the first oxide layer of the substrate.

### CROSS-REFERENCE TO RELATED APPLICATION(S)

This application claims to the benefit of and priority to a U.S. Provisional Patent Application No. 62/779,473, filed on Dec. 14, 2018, the entire content of which is incorporated by reference herein.

### FIELD

The present disclosure generally relates to a method of forming high aspect ratio (HAR) features (such as trenches or holes) in a semiconductor substrate. More specifically, the present disclosure relates to a method of forming capacitors in a semiconductor substrate for a dynamic random-access memory (DRAM) device by using end point detection.

### BACKGROUND

Conventionally, in a semiconductor device manufacturing process, a plasma based etching process has been used for etching a substrate (e.g., a semiconductor wafer) in a processing chamber. For the manufacturing of dynamic random-access memory (DRAM) devices, the plasma etching process is used to form capacitors of the DRAM devices. The substrate for forming DRAM capacitors has a mask layer, a dielectric layer, and a bulk silicon layer. The dielectric layer includes multiple oxide layers (i.e., silicon oxide layers) and nitride layers (i.e., silicon nitride layers). The dielectric layer of the substrate is etched to form high aspect ratio (HAR) holes. Different etching gas as well as other parameters are selected for etching the oxide layers and the nitride layers. Therefore, it is important to determine whether one layer has reached an etching end point, so that the etching gas and other parameters can be adjusted for the etching process for a next layer. Usually, a time-controlled plasma etching process is used for the formation of DRAM capacitors. For example, one layer is etched for a predetermined duration based on the thickness and an etching rate of the layer, and then the etching gas and other parameters are changed for the etching process of the next layer. However, due to high aspect ratio profiles of DRAM capacitors, it is difficult to determine whether the layer has reached the etching end point; consequently, under etching and over etching often occurs in the time-controlled plasma etching process for the formation of DRAM capacitors.

FIGS. 1A and 1B are schematic diagrams showing the under etching and over etching of a semiconductor substrate. The substrate 100 includes a mask layer 130, a base layer 110, and an oxide layer 120 disposed between the mask layer 130 and the base layer 110. The mask layer 130 has an opening for etching a desired hole in the oxide layer 120. As shown in FIG. 1A, when under etching occurs, the oxide layer 120 is not sufficiently etched, and the desired hole in the oxide layer 120 is not completely opened. As shown in FIG. 1B, when over etching occurs, the base layer 110 under the oxide layer 120 is undesirably etched, and the hole in the oxide layer 120 has a bowing profile that causes damage to the structure of the hole. Both under etching and over etching impact the yield rate and the quality of the DRAM device. Therefore, it is crucial to control the length of time of the etching process.

Accordingly, there remains a need to provide a method of forming high aspect ratio holes to improve the quality and yield of the manufacturing of DRAM capacitors.

### SUMMARY

In view of above, an object of the present disclosure is to provide a method of forming high aspect ratio (HAR) features in a semiconductor substrate.

To achieve the above object, an implementation of the present disclosure provides a method of forming high aspect ratio (HAR) features in a semiconductor substrate. The method includes a plural of actions. In an action, the substrate is placed in a processing chamber of an etching apparatus. In an action, a first nitride layer of the substrate is etched towards a first oxide layer of the substrate for a predetermined duration. In an action, a first oxide layer of the substrate is etched towards a second nitride layer of the substrate while a parameter in the processing chamber is monitored by an end point detector of the etching apparatus. In an action, a control unit of the etching apparatus determines whether the parameter in the processing chamber detected by the end point detector exceeds a predetermined value. In an action, if the parameter detected by the end point detector exceeds the predetermined value, an etching end point is marked for the first oxide layer of the substrate.

Preferably, the parameter in the processing chamber is an intensity ratio of a second light over a first light. The first light is emitted from an etching product of the first oxide layer, and the second light is emitted from an etching product of the second nitride layer. The end point detector of the etching apparatus is an optical emission spectrometry detector.

As described above, an end point detector may be used to monitor the intensity ratio of lights emitted from etching products of different layers in the substrate. If the ratio exceeds the predetermined value, the etching end point of the layer can be determined. The method of the implementations of the present disclosure can determine the etching end point of the layer at high accuracy. Therefore, the method of the implementations of the present disclosure prevents the occurrence of under etching or over etching during the formation of HAR features to improve the yield rate and product quality of the semiconductor device.

### BRIEF DESCRIPTION OF THE DRAWINGS

Implementations of the present technology will now be described, by way of example only, with reference to the attached figures.

FIG. 1A is a schematic diagram showing under etching of a semiconductor substrate.

FIG. 1B is a schematic diagram showing over etching of a semiconductor substrate.

FIG. 2 is a schematic diagram of an etching apparatus according to an implementation of the present disclosure.

FIG. 3 is a schematic diagram of a semiconductor substrate to be processed in the etching apparatus of FIG. 2.

FIG. 4A is a flowchart of a method of forming high aspect ratio features in a semiconductor substrate according to another implementation of the present disclosure.

FIG. 4B is an etching condition table according to an implementation.

FIG. 4C is a schematic diagram of the semiconductor substrate with respect to the actions S401 through S406 in FIG. 4A.

FIG. 4D is a schematic diagram of the semiconductor substrate the actions S407 through S4010 in FIG. 4B.

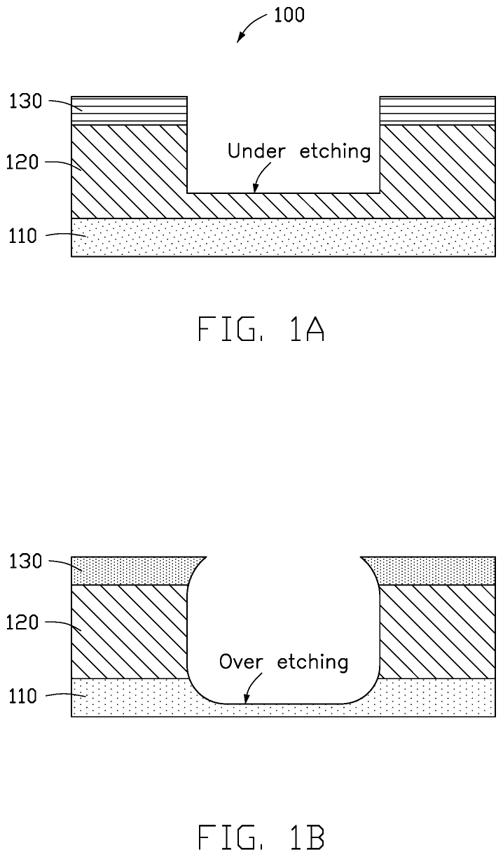

### DETAILED DESCRIPTION

The present disclosure will now be described more fully hereinafter with reference to the accompanying drawings, in which exemplary implementations of the disclosure are shown. This disclosure may, however, be embodied in many different forms and should not be construed as limited to the exemplary implementations set forth herein. Rather, these exemplary implementations are provided so that this disclosure will be thorough and complete, and will fully convey the scope of the disclosure to those skilled in the art. Like reference numerals refer to like elements throughout.

The terminology used herein is for the purpose of describing particular exemplary implementations only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” or “includes” and/or “including” or “has” and/or “having” when used herein, specify the presence of stated features, regions, integers, steps, operations, elements, and/or components, but do not preclude the presence or addition of one or more other features, regions, integers, steps, operations, elements, components, and/or groups thereof.

It will be understood that the term “and/or” includes any and all combinations of one or more of the associated listed items. It will also be understood that, although the terms first, second, third etc. may be used herein to describe various elements, components, regions, parts and/or sections, these elements, components, regions, parts and/or sections should not be limited by these terms. These terms are only used to distinguish one element, component, region, part or section from another element, component, region, layer or section. Thus, a first element, component, region, part or section discussed below could be termed a second element, component, region, layer or section without departing from the teachings of the present disclosure.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

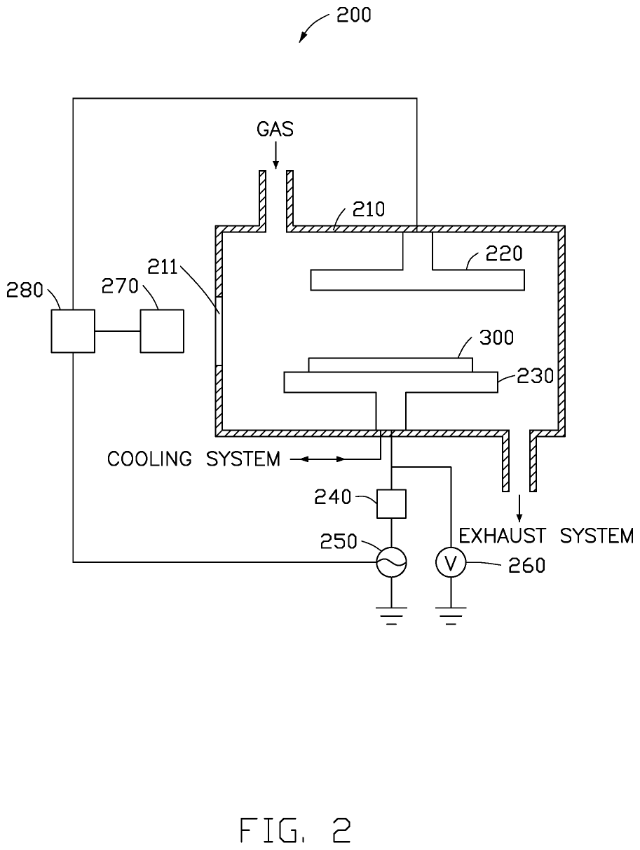

The description will be made as to the exemplary implementations of the present disclosure in conjunction with the accompanying drawings in FIGS. 2 to 4D. Reference will be made to the drawing figures to describe the present disclosure in detail, wherein depicted elements are not necessarily shown to scale and wherein like or similar elements are designated by same or similar reference numeral through the several views and same or similar terminology.

The present disclosure will be further described hereafter in combination with the accompanying figures.

Referring to FIG. 2, a schematic diagram of an etching apparatus according to an implementation of the present disclosure is illustrated. As shown in FIG. 2, the etching apparatus 200 includes a processing chamber 210 for accommodating a semiconductor substrate 300. An anode 220 and a cathode 230 are disposed in the processing chamber 210. The processing chamber 210 is connected to a gas supply system that supplies gas (such as etching gases) into the processing chamber 210. The processing chamber 210 may also be connected to an exhaust system that exhausts gas from the processing chamber 210. The cathode 230 is connected to a high-frequency power supply 250 through a matching box 240 with a voltmeter 260 for measuring a self-bias voltage. A cooling system is provided for cooling the cathode 230. The substrate 300 having a target layer to be etched is disposed on the cathode 230. An etching gas is introduced into the processing chamber 210. Then, a high-frequency power is applied to the cathode 230 by the high-frequency power supply 250 to generate a plasma between the anode 220 and the cathode 230. In the plasma, ions are present as the reaction products of the etching gas, and the ions are accelerated by an electric field and collide with the target layer of the substrate 300 to generate a chemical reaction, thus resulting in etching of the target layer. The etching apparatus 200 further includes an end point detector 270 configured to determine whether the target layer of the substrate 300 has reached an etching end point. The etching apparatus 200 may further include a control unit 280 connected to the end point detector 270 to control the operation of the etching apparatus 200. In this implementation, as shown in FIG. 2, the end point detector 270 is an optical emission spectrometry detector configured to detect an intensity of a light emitted from a light emission species in the plasma from a window 211 of the processing chamber 210. In some implementations, the end point detector 270 may be a laser interferometer configured to detect a depth of a hole or a trench etched in the target layer of the substrate 300. In some implementations, the end point detector may be a plasma impedance detector configured to detect a plasma impedance of the plasma in the processing chamber 210. Once the etching end point of the target layer is reached, the etching process for the target layer stops, and the etching apparatus 200 prepares for the etching process of another semiconductor substrate or a next layer under the target layer of the substrate 300.

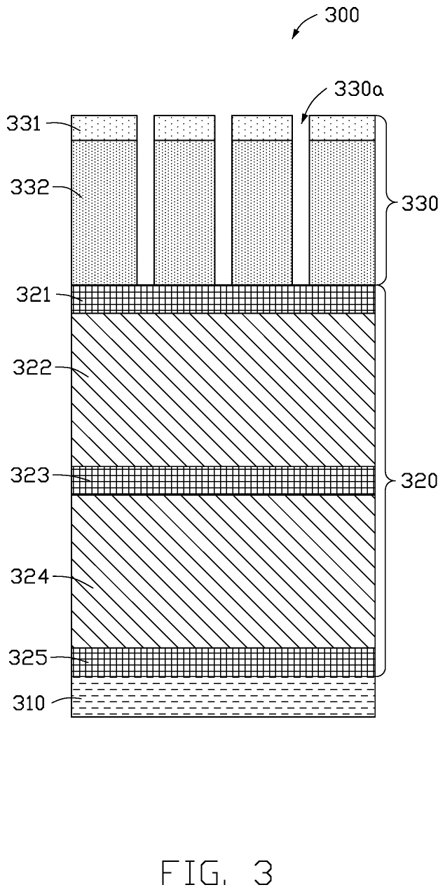

Referring to FIG. 3, a schematic diagram of the substrate 300 to be processed by the etching apparatus of FIG. 2 is illustrated. The substrate 300 is to be constructed to form capacitors of a dynamic random-access memory (DRAM) device. As shown in FIG. 3, the substrate 300 includes a dielectric layer 320 and a patterned mask 330 disposed on the dielectric layer 320. The substrate 300 further includes a base layer 310 disposed under the dielectric layer 320. The patterned mask 330 has openings 330a. The dielectric layer 320 is to be etched with high aspect ratio (HAR) holes or trenches along the openings 330a of the patterned mask 330. The patterned mask 330 includes an oxide hard mask layer 331 and a polysilicon hard mask layer 332. The base layer 310 may be made of silicon, such as monocrystalline silicon or monocrystalline silicon lightly-doped with background p-type dopants. The dielectric layer 320 includes multiple oxide layer and nitride layers, including a first nitride layer 321, a first oxide layer 322, a second nitride layer 323, a second oxide layer 324, and a third nitride layer 325 in descending order from the patterned mask 330. Each of the nitride layers 321, 323, 325 may be made of silicon nitride, and may have thicknesses ranging from, for example, about 100 Å to about 3000 Å. Each of the oxide layers 322, 324 may be made of silicon dioxide (SiO₂) or doped silicon oxide (with exemplary doped silicon oxide being, for example, borophosphosilicate glass (BPSG) and phosphosilicate glass (PSG)).

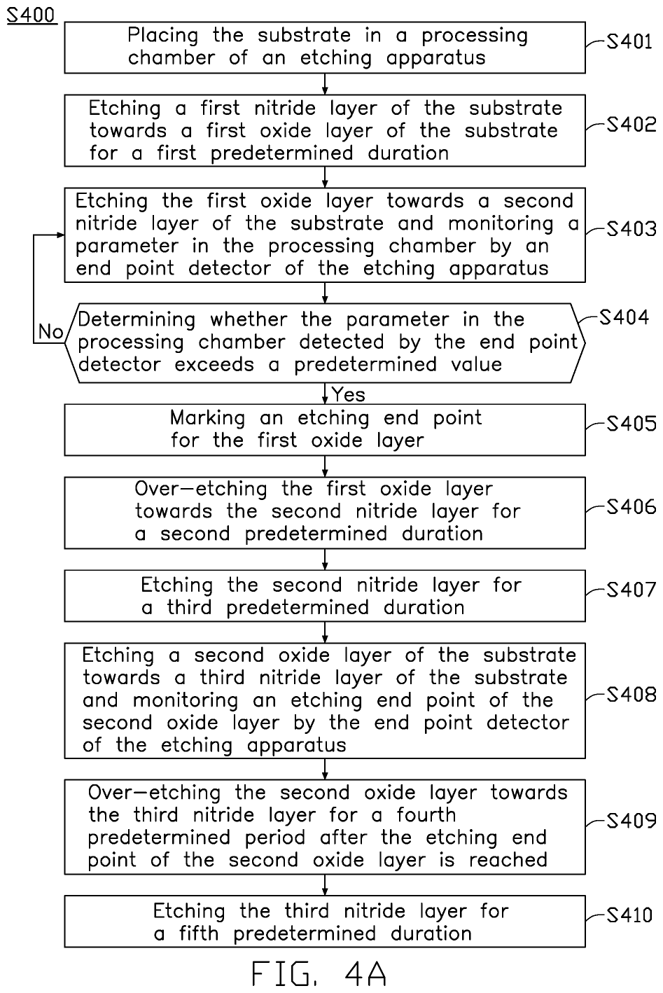

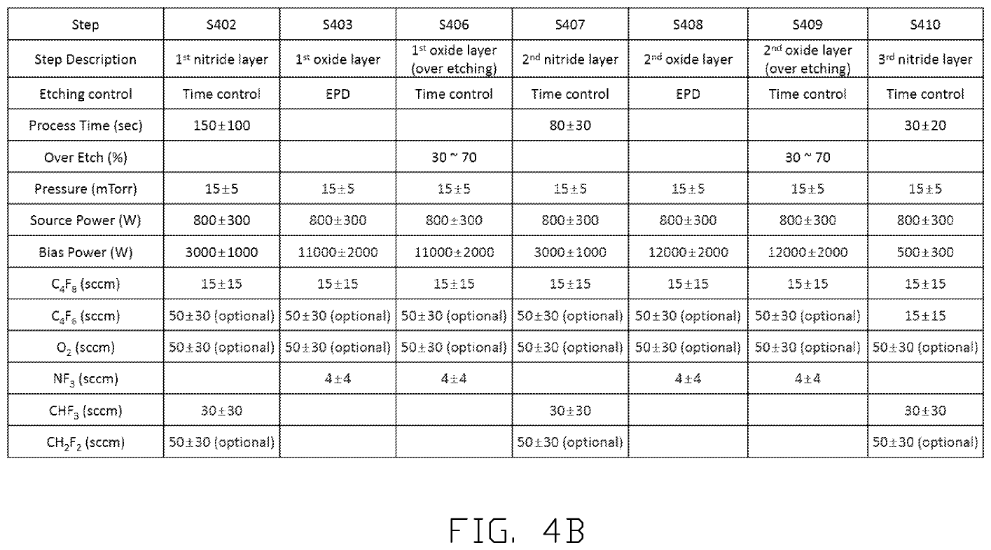

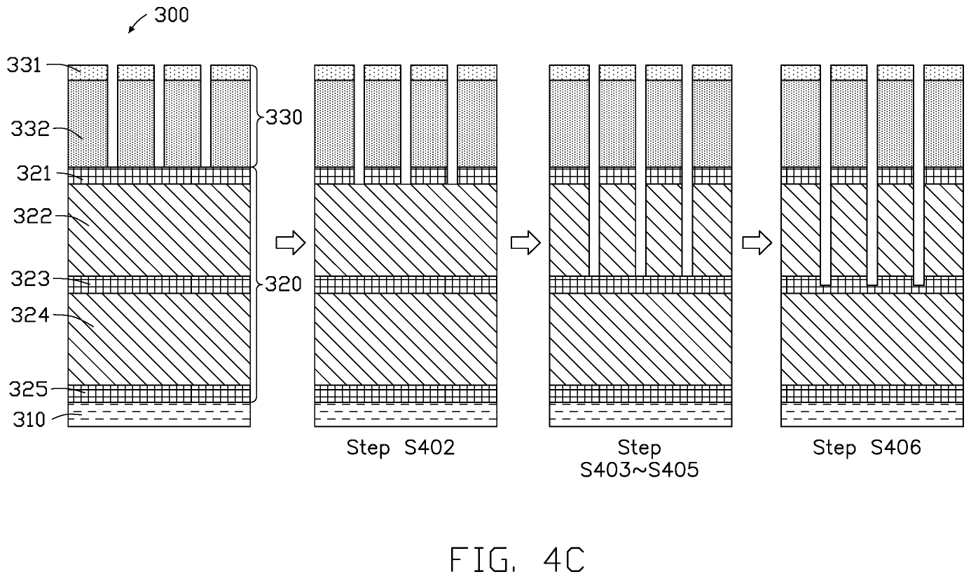

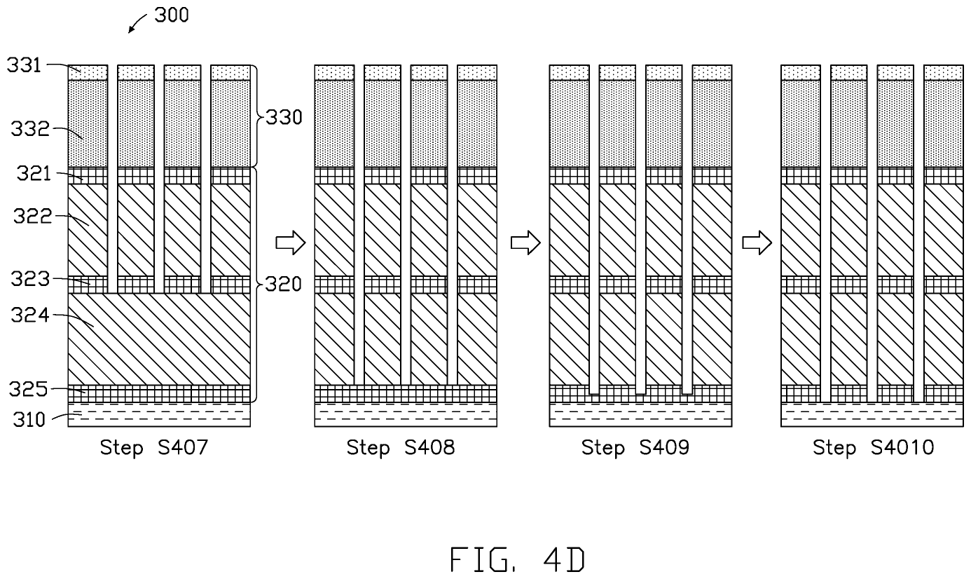

Referring to FIGS. 4A to 4D, FIG. 4A is a flowchart of a method S400 of forming high aspect ratio features in a semiconductor substrate according to another implementation of the present disclosure. FIG. 4B shows an etching condition table for the method of FIG. 4A. FIGS. 4C and 4D are schematic diagrams of the semiconductor substrate throughout the actions of the method of FIG. 4A. The method S400 includes actions S401 to S410. The semiconductor substrate can be referred to the semiconductor substrate 300 of FIG. 3. The substrate 300 is to be constructed to form capacitors of a DRAM device. The substrate 300 includes a dielectric layer 320 and a patterned mask 330 disposed on the dielectric layer 320. The substrate 300 further includes a base layer 310 disposed under the dielectric layer 320. The patterned mask 330 has openings 330a. The dielectric layer 320 is to be etched with high aspect ratio (HAR) holes or trenches along the openings 330a of the patterned mask 330. The patterned mask 330 includes an oxide hard mask layer 331 and a polysilicon hard mask layer 330. The base layer 310 may be made of silicon, such as monocrystalline silicon or monocrystalline silicon lightly-doped with background p-type dopants. The dielectric layer 230 includes multiple oxide layer and nitride layers, including a first nitride layer 321, a first oxide layer 322, a second nitride layer 323, a second oxide layer 324, and a third nitride layer 325 in descending order from the patterned mask 330. Each of the nitride layers 321, 323, 325 may be made of silicon nitride, and may have thicknesses ranging from, for example, about 100 Å to about 3000 Å. Each of the oxide layers 322, 324 may be made of silicon dioxide (SiO₂) or doped silicon oxide. Specifically, the method S400 may be a method of forming capacitors for a DRAM device in the substrate 300. Also note that, prior to action S401, the openings 330a have been formed on the patterned mask 330 of the semiconductor substrate 300.

In action S401, the substrate 300 is placed in a processing chamber of an etching apparatus. The etching apparatus can be referred to the etching apparatus 200 of FIG. 2. The etching apparatus 200 includes the processing chamber 210 for accommodating the substrate 300. An anode 220 and a cathode 230 are disposed in the processing chamber 210. The processing chamber 210 is connected to a gas supply system that supplies gas (such as etching gases) into the processing chamber 210. The processing chamber 210 may be also connected to an exhaust system that exhausts gas from the processing chamber 210. The cathode 230 is connected to a high-frequency power supply 250 through a matching box 240 with a voltmeter 260 for measuring a self-bias voltage. A cooling system is provided for cooling the cathode 230. The substrate 300 is disposed on the cathode 230 of the etching apparatus 200.

In action S402, the first nitride layer 321 is etched towards the first oxide layer 322 for a first predetermined duration. As shown in FIG. 4B, the first nitride layer is etched under a mixed gas of octafluorocyclobutane (C₄F₈) and fluoroform (CHF₃) into the processing chamber 210. After the mixed gas of C₄F₈ and CHF₃ is introduced into the processing chamber 210, a high-frequency power is applied to the cathode 230 by the high-frequency power supply 250 to generate a plasma between the anode 220 and the cathode 230. In the plasma, ions are present as the reaction products of the C₄F₈ and the CHF₃, and the ions are accelerated by an electric field and collide with the first nitride layer 321 of the substrate 300 to generate a chemical reaction, thus resulting in etching of the first nitride layer 321. The first nitride layer 321 is etched by a time-controlled manner (i.e., etched for the first predetermined duration). The first predetermined duration for etching the first nitride layer 321 is determined based on a thickness of the first nitride layer 321 and an etching rate for the first nitride layer 321 by the C₄F₈ and the CHF₃. The C₄F₈ is provided at a flow rate within a range of 5 sccm to 30 sccm. The CHF₃ is provided at a flow rate within a range of 5 sccm to 60 sccm. When etching the first nitride layer 321, the etching apparatus 200 is operated under a source power within a range of 500 W to 1100 W, and a bias power within a range of 2000 W to 4000 W. A pressure of the processing chamber 210 is within a range of 10 mTorr to 20 mTorr. The first predetermined duration for etching the first nitride layer 321 is within a range of 50 seconds to 250 seconds. The first nitride layer 321 may be further etched under at least one gas selected from hexafluoro-1,3-butadiene (C₄F₆), oxygen (O₂), and difluoromethane (CH₂F₂). The C₄F₆ may be provided at a flow rate within a range of 20 sccm to 80 sccm. The O₂ may be provided at a flow rate within a range of 20 sccm to 80 sccm. The CH₂F₂ may be provided at a flow rate within a range of 20 sccm to 80 sccm. The schematic diagram of the substrate 300 after action S402 is illustrated in action S402 shown in FIG. 4C.

In action S403, the first oxide layer 322 is etched towards the second nitride layer 323, while a parameter in the processing chamber 231 is monitored by an end point detector of the etching apparatus 200. In the implementation as shown in FIG. 2, the end point detector 270 may be an optical emission spectrometry detector, and the parameter in the processing chamber 210 is an intensity ratio of a second light over a first light. The first light is emitted from an etching product of the first oxide layer 322, and has a first wavelength. Specifically, the first light is emitted from an oxygen-containing species in the plasma. The oxygen-containing species in the plasma is an etching product of the first oxide layer 322. For example, the oxygen-containing species may be oxygen atom. The second light is emitted from an etching product of the second nitride layer 323, and has a second wavelength that is different from the first wavelength. Specifically, the second light is emitted from a nitrogen-containing species in the plasma. The nitrogen-containing species in the plasma is an etching product of the second nitride layer 323. For example, the nitrogen-containing species may be nitrogen atoms.

In some implementations, the end point detector of the etching apparatus 200 may be a laser interferometer, and the parameter in the processing chamber monitored by the end point detector is a depth of the holes or the trenches etched in the first oxide layer 322.

In some implementations, the end point detector of the etching apparatus 200 may be a plasma impedance detector, and the parameter in the processing chamber 210 monitored by the end point detector is a plasma impedance in the processing chamber 210.

Referring to FIG. 4B again, the first oxide layer 322 is etched under a mixed gas of octafluorocyclobutane (C₄F₈) and nitrogen trifluoride (NF₃). The C₄F₈ is provided at a flow rate within a range of 5 sccm to 30 sccm, and the NF₃ is provided at a flow rage within a range of below 8 sccm (preferably 2 sccm to 8 sccm). When etching first oxide layer 322, the etching apparatus 200 is operated under a source power within a range of 500 W to 1100 W and a bias power within a range of 9000 W to 13000 W. The first oxide layer 322 is etched under a pressure of the processing chamber within a range of 10 mTorr to 20 mTorr. The first oxide layer 322 is further etched under at least one gas selected from hexafluoro-1,3-butadiene (C₄F₆) and oxygen (O₂). The C₄F₆ is provided at a flow rate within a range of 20 sccm to 50 sccm, and the O₂ is provided at a flow rate within a range of 20 sccm to 50 sccm.

In action S404, the control unit 280 of the etching apparatus 200 determines whether the parameter in the processing chamber 210 detected by the end point detector exceeds a predetermined value. In action S405, the control unit 280 of the etching apparatus 200 marks an etching end point for the first oxide layer 322. In one implementation, the end point detector 270 is an optical emission spectrometry detector, and the parameter in the processing chamber 210 is an intensity ratio of a second light over a first light. The first light is emitted from an etching product of the first oxide layer 322, and has a first wavelength. Specifically, the first light is emitted from an oxygen-containing species in the plasma. The oxygen-containing species in the plasma is an etching product of the first oxide layer 322. The second light is emitted from an etching product of the second nitride layer 323, and has a second wavelength that is different from the first wavelength. Specifically, the second light emitted from a nitrogen-containing species in the plasma. The nitrogen-containing species in the plasma is an etching product of the second nitride layer 323. The intensity of the first light has a positive correlation with a concentration of the etching product of the first oxide layer 322 in the processing chamber. The intensity of the second light has a positive correlation with a concentration of the etching product of the second nitride layer 323. When the first oxide layer 322 reaches its etching end point, the plasma begins to react with the third nitride layer 325 and produces the nitrogen-containing species in the plasma. Therefore, the intensity of the second light begins to increase at the etching end point of the first oxide layer 322, whereas the intensity of the first light may begin to decrease. By monitoring the intensity ratio of the second light over the first light, the etching end point of the first oxide layer 322 can be detected. Furthermore, due to the high aspect ratio profiles of the desired holes or trenches, the intensity of the second light is very weak as compared to the intensity of the first light. The intensity of the second light may be amplified by a magnitude of 100,000 to 10,000,000. The schematic diagrams of the substrate 300 after action S405 are also illustrated as “S403˜S405” in FIG. 4C.

In some implementations, the end point detector of the etching apparatus 200 may be a laser interferometer, and the parameter in the processing chamber monitored by the end point detector is a depth of the holes or the trenches etched in the first oxide layer 322. The etching end point of the first oxide layer 322 is marked when the depth of the holes or the trenches has reached a bottom of the first oxide layer 322.

In some implementations, the end point detector of the etching apparatus 200 may be a plasma impedance detector, and the parameter in the processing chamber 210 monitored by the end point detector is a plasma impedance in the processing chamber 210. When the etching end point of the first oxide layer 322 has reached, the plasma impedance in the processing chamber 210 is changed by the etching product (i.e., nitrogen-containing species) of the third nitride layer 323. Therefore, the etching end point of the first oxide layer 322 can be detected.

In action S406, the first oxide layer 322 is over-etched towards the second nitride layer 323 for a second predetermined duration. The second predetermined duration for etching the first oxide layer 322 is set to achieve an over-etching percentage of 30% to 70%, preferably 30% to 50%. For example, if the processing time for reaching the etching end point for the first oxide layer is 200 seconds, the processing time for over-etching the first oxide layer is 100 seconds at 50% of over-etching. As shown in FIG. 4B, other processing conditions of action S406 are similar to those of action S403 without further description herein. The schematic diagram of the substrate 300 after action S406 is illustrated in action S406 shown in FIG. 4C.

In action S407, the second nitride layer 323 is etched for a third predetermined duration. The third predetermined duration may be determined based on a thickness of the second nitride layer 323 and an etching rate of the second nitride layer 323. The third predetermined duration is within a range of 50 seconds to 110 seconds. As shown in FIG. 4B, other processing condition of action S407 are similar to those of action S402 without further description herein. The schematic diagram of the substrate 300 after action S407 is illustrated in action S407 of FIG. 4D.

In action S408, the second oxide layer 324 is etched towards the third nitride layer 325, while an etching endpoint end point of the second oxide layer 324 is monitored by the end point detector of the etching apparatus 200. In action S409, the second oxide layer 324 is over-etched towards the third nitride layer 325 for a fourth predetermined duration after the etching end point of the second oxide layer 324 is reached. As shown in FIG. 4B, the processing conditions of actions S408 and S409 are the same to those of actions S406 and S407 without further description herein. The schematic diagrams of the substrate 300 after actions S408 and S409 are illustrated in actions S408 and S409 of FIG. 4D.

In action S410, the third nitride layer 325 is etched for a fifth predetermined duration. The fifth predetermined duration may be within a range of 10 seconds to 50 seconds. As shown in FIG. 4B, other processing condition of action S410 are similar to those of action S402 without further description herein. The schematic diagram of the substrate 300 after action S410 is illustrated in action S410 of FIG. 4D. After action S410, the desired high aspect ratio holes or trenches are formed in the substrate 300, and the substrate 300 may be processed by subsequent processes (such as conductive layer formation process, sacrificial layer removal process, and etc.) to form the capacitors for the DRAM device.

As described above, the method of the implementations of the present disclosure uses an end point detector to monitor the intensity ratio of lights emitted from etching products of different layers in the substrate. If the ratio exceeds the predetermined value, the etching end point of the layer can be determined. The method of the implementations of the present disclosure can determine the etching end point of the layer at high accuracy. Therefore, the method of the implementations of the present disclosure prevents the occurrence of under etching or over etching during the formation of HAR features to improve the yield rate and product quality of the semiconductor device.

The implementations shown and described above are only examples. Many details are often found in the art such as the other features of a method of forming HAR features in a semiconductor substrate. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the implementations described above may be modified within the scope of the claims.

What is claimed is:

1. A method of forming high aspect ratio (HAR) features in a semiconductor substrate, the method comprising:
placing the substrate in a processing chamber of an etching apparatus;
etching a first nitride layer of the substrate towards a first oxide layer of the substrate for a first predetermined duration;
etching the first oxide layer towards a second nitride layer of the substrate and monitoring a parameter in the processing chamber by an end point detector of the etching apparatus;
determining whether the parameter in the processing chamber detected by the end point detector exceeds a predetermined value; and
marking an etching end point for the first oxide layer if the parameter detected by the end point detector exceeds the predetermined value.

2. The method of claim 1, wherein the end point detector is a laser interferometer, and the parameter is a depth of a hole or a trench etched in the first oxide layer.

3. The method of claim 1, wherein the end point detector is an optical emission spectrometry detector, the parameter is an intensity ratio of a second light over a first light, the first light is emitted from an etching product of the first oxide layer, and the second light is emitted from an etching product of the second nitride layer.

4. The method of claim 1, wherein the end point detector is a plasma impedance detector, and the parameter is a plasma impedance in the processing chamber.

5. The method of claim 1, wherein the first predetermined duration for etching the first nitride layer is determined based on a thickness of the first nitride layer and an etching rate of the first nitride layer.

6. The method of claim 1, further comprising:
over-etching the first oxide layer towards the second nitride layer after the etching end point for the first oxide layer is reached.

7. The method of claim 6, wherein the first oxide layer is over-etched for a second predetermined duration.

8. The method of claim 7, further comprising:
etching the second nitride layer for a third predetermined duration after the first oxide layer is over-etched.

9. The method of claim 8, wherein the third predetermined duration is determined based a thickness of the second nitride layer and an etching rate of the second nitride layer.

10. The method of claim 8, wherein the third predetermined duration for etching the second nitride layer is within a range of 50 seconds to 110 seconds.

11. The method of claim 1, wherein the first nitride layer is etched under a mixed gas of octafluorocyclobutane (C₄F₈) and fluoroform (CHF₃).

12. The method of claim 11, wherein when etching the first nitride layer, the C₄F₈ is provided at a flow rate within a range of 5 sccm to 30 sccm, and the CHF₃ is provided at a flow rate within a range of 5 sccm to 60 sccm.

13. The method of claim 11, wherein when etching the first nitride layer, the etching apparatus is operated under a source power within a range of 500 W to 1100 W and a bias power within a range of 2000 W to 4000 W.

14. The method of claim 11, wherein the first nitride layer is etched under a pressure of the processing chamber within a range of 10 mTorr to 20 mTorr.

15. The method of claim 11, wherein the first predetermined duration for etching the first nitride layer is within a range of 50 seconds to 250 seconds.

16. The method of claim 11, wherein the first nitride layer is further etched under at least one gas selected from hexafluoro-1,3-butadiene (C₄F₆), oxygen (O₂), and difluoromethane (CH₂F₂).

17. The method of claim 1, wherein the first oxide layer is etched under a mixed gas of octafluorocyclobutane (C₄F₈) and nitrogen trifluoride (NF₃).

18. The method of claim 17, wherein when etching the first oxide layer, the C₄F₈ is provided at a flow rate within a range of 5 sccm to 30 sccm, and the NF₃ is provided at a flow rage within a range of 2 sccm to 8 sccm.

19. The method of claim 17, wherein when etching the first oxide layer, the etching apparatus is operated under a source power within a range of 500 W to 1100 W and a bias power within a range of 9000 W to 13000 W.

20. The method of claim 17, wherein the first oxide layer is etched under a pressure of the processing chamber within a range of 10 mTorr to 20 mTorr.
